(19) United States
(12) Patent Application Publication
(10) Pub. No.: US 2026/0271489 A1
(43) Pub. Date: Sep. 10, 2026

(54) LIGHT-EMITTING ELEMENT AND DISPLAY DEVICE

(71) Applicant: Sharp Display Technology Corporation, Kameyama City, Mie (JP)

(72) Inventors: Keisuke KITANO, Sakai City, Osaka (JP); YOSHIHIRO UETA, Sakai City, Osaka (JP)

(21) Appl. No.: 19/105,644

(22) PCT Filed: Aug. 22, 2022
(86) PCT No.: PCT/JP2022/031521

§ 371 Date: Feb. 21, 2025

(51) Int. Cl. H10K 50/115

(52) U.S. Cl. CPC H10K 50/115

(57) ABSTRACT

A light-emitting element includes an anode and a cathode, and a light-emitting layer located between the anode and the cathode. The light-emitting layer includes a plurality of quantum dots and a matrix material including a p-type semiconductor portion and filling a space between the plurality of quantum dots.

### TECHNICAL FIELD

The disclosure relates to a light-emitting element and a display device.

### BACKGROUND ART

PTL 1 discloses a hole transport layer containing a metal oxide and carbon adjusted to a predetermined content rate.

### CITATION LIST

### Patent Literature

PTL 1: WO 2020/065944 (published on Apr. 2, 2020)

### SUMMARY

### Technical Problem

Light-emitting elements in the related art have a problem of low luminous efficiency.

### Solution to Problem

A light-emitting element according to an aspect of the disclosure includes an anode and a cathode, and a light-emitting layer located between the anode and the cathode. The light-emitting layer includes a plurality of quantum dots and a matrix material including a p-type semiconductor portion and filling a space between the plurality of quantum dots.

### Advantageous Effects of Disclosure

According to one aspect of the disclosure, it is possible to improve luminous efficiency.

### BRIEF DESCRIPTION OF DRAWINGS

FIG. 1 is a cross-sectional view illustrating a configuration example of a light-emitting element according to an embodiment of the disclosure.

FIG. 2 is a schematic view illustrating an example of a region between quantum dots illustrated in FIG. 1.

FIG. 3 is a schematic view illustrating another example of a region between quantum dots illustrated in FIG. 1.

FIG. 4 is a cross-sectional view illustrating a configuration example of a light-emitting element according to a comparative example.

FIG. 5 is a schematic view illustrating an example of a band structure of a light-emitting layer according to the disclosure illustrated in FIG. 1.

FIG. 6 is a schematic view illustrating a band structure of a light-emitting layer according to the comparative example illustrated in FIG. 4.

FIG. 7 is a flowchart illustrating an example of a method for manufacturing the light-emitting element illustrated in FIG. 1.

FIG. 8 includes cross-sectional process views illustrating an example of a forming process of the light-emitting layer according to an embodiment of the disclosure.

FIG. 9 includes cross-sectional process views illustrating an example of a forming process of the light-emitting layer according to an embodiment of the disclosure.

FIG. 10 is a flowchart illustrating another example of a method for manufacturing the light-emitting element illustrated in FIG. 1.

FIG. 11 includes cross-sectional process views illustrating an example of a forming process of the light-emitting layer according to an embodiment of the disclosure.

FIG. 12 includes cross-sectional process views for describing a substitution step.

FIG. 13 is a schematic view illustrating a quantum dot dispersion liquid.

FIG. 14 is a cross-sectional view illustrating a modified example of the configuration of the light-emitting element according to the above embodiment of the disclosure.

FIG. 15 is a cross-sectional view illustrating a modified example of the configuration of the light-emitting element according to the above embodiment of the disclosure.

FIG. 16 is a cross-sectional view illustrating a configuration example of the light-emitting element according to an embodiment of the disclosure.

FIG. 17 includes schematic views illustrating an example of the forming process of the light-emitting layer according to an embodiment of the disclosure.

FIG. 18 is a plan view illustrating a configuration example of a display device according to an embodiment of the disclosure.

### DESCRIPTION OF EMBODIMENTS

### First Embodiment

### Cross-Sectional Configuration of Light-Emitting Element

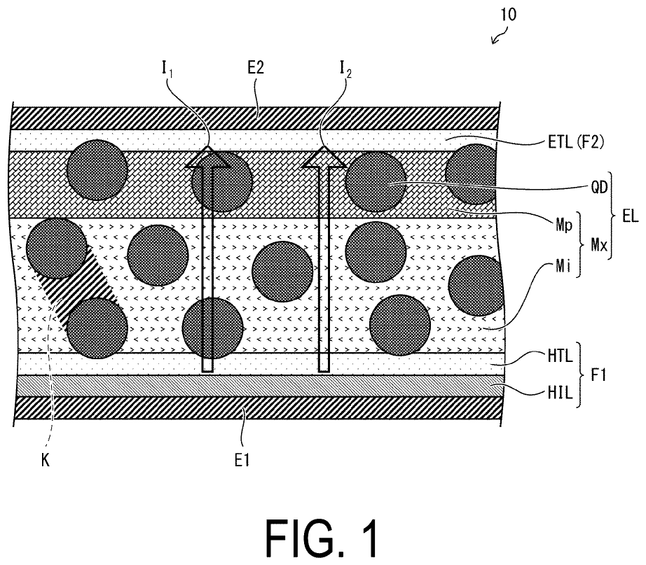

FIG. 1 is a cross-sectional view illustrating a configuration example of a light-emitting element according to an embodiment of the disclosure. As illustrated in FIG. 1, a light-emitting element 10 according to the present embodiment includes an anode E1 and a cathode E2 facing each other, and a light-emitting layer EL located between the anode E1 and the cathode E2. The light-emitting layer EL includes a plurality of quantum dots QD located between the anode E1 and the cathode E2, and a matrix material Mx configured to fill a space between the plurality of quantum dots QD. The matrix material Mx includes a p-type semiconductor portion Mp and an i-type semiconductor portion Mi. The matrix material Mx may change continuously or stepwise from the i-type semiconductor portion Mi to the p-type semiconductor portion Mp. The matrix material Mx may be formed of an inorganic semiconductor.

The light-emitting element 10 may further include one or both of a charge function layer F1 located between the anode E1 and the light-emitting layer EL and a charge function layer F2 located between the cathode E2 and the light-emitting layer EL. The charge function layer F1 may include any one or more of a hole injection layer HIL, a hole transport layer HTL, and an electron blocking layer. The charge function layer F2 may include any one or more of an electron injection layer, an electron transport layer ETL, and a hole blocking layer. The current flowing through the light-emitting layer EL includes a current I₁ that flows through the quantum dot QD and contributes to light emission and a current I₂ that flows while avoiding the quantum dot QD and does not contribute to light emission.

The matrix material Mx means a member that contains and holds other objects, and can be referred to as a base material, a matrix, or a filler. The matrix material Mx may be solid at room temperature. The matrix material Mx may be an inorganic matrix material formed of an inorganic material (for example, an inorganic semiconductor). The matrix material Mx may be a member that contains and holds the plurality of quantum dots QD. The matrix material Mx may be a constituent element of the light-emitting layer EL including the plurality of quantum dots QD.

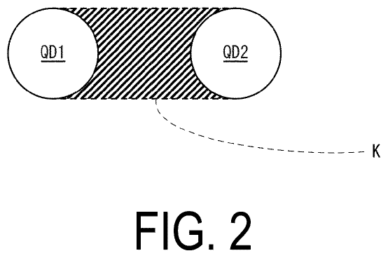

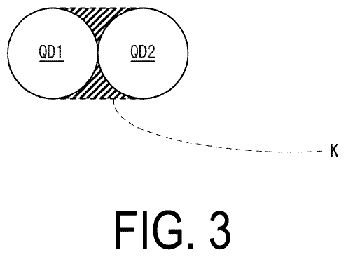

FIG. 2 and FIG. 3 are each a schematic view illustrating an example of a region between the quantum dots illustrated in FIG. 1. The matrix material Mx may be filled in the light-emitting layer EL. As illustrated in FIG. 1. the matrix material Mx preferably may be configured to fill a region (space) other than the plurality of quantum dots QD in the light-emitting layer EL. Focusing on two quantum dots QD among the plurality of quantum dots QD, the matrix material Mx may be configured to fill a region (space) K between the two quantum dots QD. The two quantum dots QD are referred to as a first quantum dot QD1 and a second quantum dot QD2. As illustrated in FIG. 2 and FIG. 3, the region K is a region surrounded by two straight lines (external common tangent) circumscribing the outer peripheries of the first and second quantum dots QD1 and QD2 and the facing outer peripheries of the first and second quantum dots QD1 and QD2 in a cross-sectional view. As illustrated in FIG. 3, the region K can exist even when the first quantum dot QD1 is near the second quantum dot QD2. “Filling a space between a plurality of quantum dots” simply means filling a space between two quantum dots as illustrated in FIG. 2 (or FIG. 3). The matrix material Mx with which the region K is filled may be the p-type semiconductor portion Mp, the i-type semiconductor portion Mi, or both of the p-type semiconductor portion Mp and the i-type semiconductor portion Mi.

The matrix material Mx may be configured to fill a region (space) other than a quantum dot group in the light-emitting layer EL. Here, three or more quantum dots QD are collectively referred to as a quantum dot group. The matrix material Mx may be configured to fill a region (space) other than the plurality of quantum dots QD in the light-emitting layer EL.

The outer edge (upper surface and lower surface) of the light-emitting layer EL may be covered with the matrix material Mx. In addition, a portion of the matrix material Mx may extend from the outer edge of the light-emitting layer EL, and the quantum dots QD may be located away from the outer edge. The outer edge of the light-emitting layer EL does not need to be formed of only the matrix material Mx, and the quantum dots QD may be partially exposed from the matrix material Mx. The matrix material Mx may be a portion of the light-emitting layer EL excluding the plurality of quantum dots QD. The matrix material Mx covering the outer edge of the light-emitting layer EL may be the p-type semiconductor portion Mp, the i-type semiconductor portion Mi, or both of the p-type semiconductor portion Mp and the i-type semiconductor portion Mi.

The matrix material Mx may include the plurality of quantum dots QD. The matrix material Mx may be formed so as to fill spaces formed between the plurality of quantum dots QD. The plurality of quantum dots QD may be embedded in the matrix material Mx at intervals. The matrix material Mx may be configured to partially or completely fill spaces between the plurality of quantum dots QD.

The matrix material Mx may include a continuous film having an area equal to or larger than 1000 nm² in a plane direction orthogonal to a film thickness direction. The continuous film means a film that is not separated by a material other than a material constituting the continuous film in one plane. A part of the continuous film may be the p-type semiconductor portion Mp and the other part may be the i-type semiconductor portion Mi.

The matrix material Mx may be the same material as the shell included in each of the plurality of quantum dots QD. In this case, an average distance between adjacent cores (core-to-core distance) to each other may be equal to or greater than 3 nm or may be equal to or greater than 5 nm. Alternatively, the average distance between adjacent cores may be 0.5 times or more the average core diameter. The core-to-core distance is obtained by averaging the shortest distances between 20 adjacent cores. The core-to-core distance may be kept wider than the distance when the shells are in contact with each other. The average core diameter is obtained by averaging the core diameters of 20 adjacent cores in a cross-sectional observation. The core diameter can be the diameter of a circle having the same area as the core area in the cross-sectional observation.

The concentration of the matrix material Mx in the light-emitting layer EL may be equal to or greater than 0.1% and equal to or less than 79.0%. The concentration may be measured, for example, from an area ratio in image processing in the cross-sectional observation. In addition, when the quantum dots QD have a core/shell structure, the concentration of the shell may be equal to or greater than 0.1% and equal to or less than 39%. In a case where the shell and the matrix material Mx are made of the same material (same composition) and the shell and the matrix material Mx cannot be distinguished from each other, the concentration of the shell and the matrix material Mx in the region of a mix of the shell and the matrix material Mx may be equal to or greater than 0.1% and equal to or less than 99.9%. As described above, when the shell and the matrix material Mx cannot be distinguished from each other, the shell may be a part of the matrix material Mx.

The light-emitting layer EL may be composed of the plurality of quantum dots QD and the matrix material Mx. The intensity of carbon in the chain structure detected when the light-emitting layer EL is analyzed may be equal to or less than noise level.

It is desirable that the constituent material of the matrix material Mx have a wider band gap than the constituent material (for example, the core material) of the quantum dot QD. As a material constituting the matrix material Mx, a semiconductor or an insulator can be used. Examples of the constituent material of the matrix material Mx include, for example, a metal sulfide and/or a metal oxide. The metal sulfide may be, for example, zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). The metal oxide may be zinc oxide (ZnO), titanium oxide (TiO₂), tin oxide (SnO₂), tungsten oxide (WO₃), and zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

In the structure of the matrix material Mx, the configuration described above need not be observed over the entire area of the light-emitting layer EL as long as the structure is detected as the configuration described above by observing the cross section of the light-emitting layer EL in the range of about 100 nm. The matrix material Mx may contain a substance different from the main material (for example, an inorganic substance such as an inorganic semiconductor), for example, as an additive.

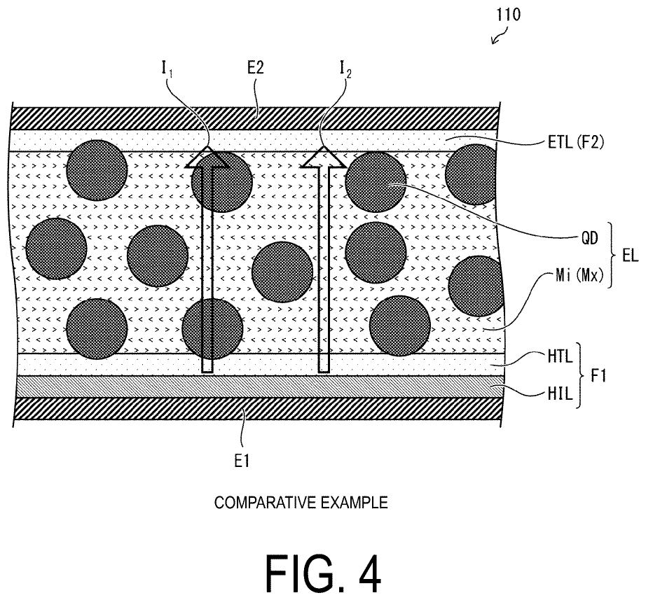

FIG. 4 is a cross-sectional view illustrating a configuration example of the light-emitting element according to the comparative example. As illustrated in FIG. 4, the matrix material Mx in a light-emitting element 110 of the comparative example does not have the p-type semiconductor portion but has the i-type semiconductor portion Mi.

### P-Type Semiconductor Portion and I-Type Semiconductor Portion

The p-type semiconductor portion Mp is a portion in which the inorganic semiconductor constituting the matrix material Mx is a p-type semiconductor. On the other hand, the i-type semiconductor portion Mi is a portion in which the inorganic semiconductor constituting the matrix material Mx is an i-type semiconductor. Such a difference in the type of the inorganic semiconductor can be achieved by the doping to the inorganic semiconductor or by adjusting the composition ratio of the inorganic semiconductor.

The matrix material Mx includes, for example, a group IV semiconductor. The i-type group IV semiconductor means an inorganic semiconductor composed of one or more kinds of group 14 elements. In the disclosure, a notation of the number of groups of elements by using Roman numerals is a notation of the number based on the old International Union of Pure and Applied Chemistry (IUPAC) system, and a notation of the number of groups of elements by using Arabic numerals is a notation of the number based on the current IUPAC system. The matrix material Mx can contain one or more elements selected from carbon (C), silicon (Si), germanium (Ge), and tin (Sn).

When the matrix material Mx includes a group IV semiconductor, the p-type semiconductor portion Mp may include a p-type group IV semiconductor, and the i-type semiconductor portion Mi may include an i-type group IV semiconductor. The p-type group IV semiconductor may be a group IV semiconductor doped with a group III element. That is, the p-type semiconductor portion Mp can contain a group III element, and can contain, for example, one or more elements selected from boron (B), aluminum (Al), gallium (Ga), indium (In), and thallium (Tl).

The matrix material Mx includes, for example, a group III-V semiconductor. The i-type group III-V semiconductor means an inorganic semiconductor containing a group III element and a group V element at a composition ratio of about 1:1. The matrix material Mx can contain one or more elements selected from boron (B), aluminum (Al), gallium (Ga), indium (In), and thallium (Tl), and one or more elements selected from nitrogen (N), phosphorus (P), arsenic (As), antimony (Sb), and bismuth (Bi).

When the matrix material Mx includes a group III-V semiconductor, the p-type semiconductor portion Mp may include a p-type group III-V semiconductor, and the i-type semiconductor portion Mi may include an i-type group III-V semiconductor. The p-type group III-V semiconductor may be a group III-V semiconductor doped with a group II element and/or may be a group III-V semiconductor containing a group V element more than a ratio of 1:1 relative to a group III element. That is, the p-type semiconductor portion Mp can contain a group II element, and can contain, for example, one or more elements selected from magnesium (Mg), zinc (Zn), cadmium (Cd), and mercury (Hg). And/or, the p-type semiconductor portion Mp may contain a group V element more than a ratio of 1:1 relative to a group III element. A group III-V semiconductor containing a group V element more than a ratio of 1:1 relative to a group III element is also referred to as a “group V element-rich” group III-V semiconductor.

The matrix material Mx includes, for example, a group II-VI semiconductor. The i-type group II-VI semiconductor means an inorganic semiconductor containing a group II element and a group VI element at a composition ratio of about 1:1. The matrix material Mx can contain one or more elements selected from magnesium (Mg), zinc (Zn), cadmium (Cd), and mercury (Hg), and one or more elements selected from oxygen (O), sulfur(S), selenium (Se), and tellurium (Te).

When the matrix material Mx includes a group II-VI semiconductor, the p-type semiconductor portion Mp may include a p-type group II-VI semiconductor, and the i-type semiconductor portion Mi may include an i-type group II-VI semiconductor. The p-type group II-VI semiconductor may be a group II-VI semiconductor doped with a group IV element and/or may be a group II-VI semiconductor containing a group VI element more than a ratio of 1:1 relative to a group II element. That is, the p-type semiconductor portion Mp may contain a group IV element, particularly a group 14 element, and can contain, for example, one or more elements selected from carbon (C), silicon (Si), germanium (Ge), and tin (Sn). In particular, the p-type semiconductor portion Mp can include carbon (C). And/or, the p-type semiconductor portion Mp may contain a group VI element more than a ratio of 1:1 relative to a group II element. A group II-VI semiconductors containing a group VI element more than a ratio of 1:1 relative to a group II element is also referred to as a “group VI element-rich” group II-VI semiconductor.

### Band Structure of Light-Emitting Layer

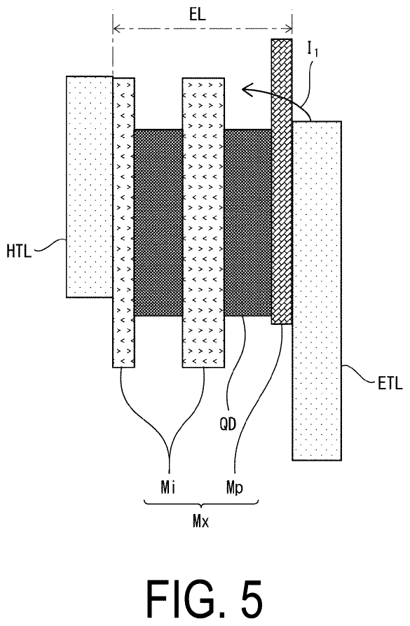

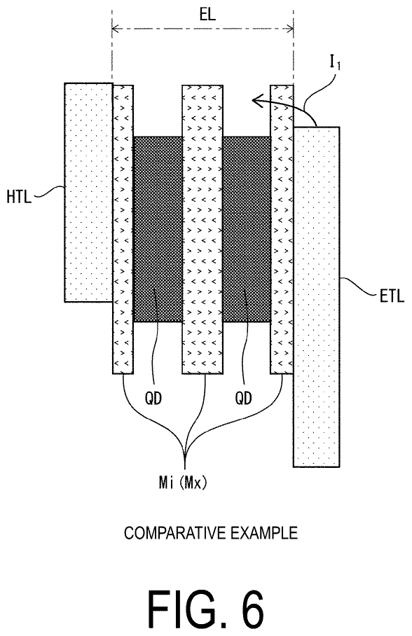

FIG. 5 is a schematic view illustrating an example of a band structure of the light-emitting layer according to the disclosure illustrated in FIG. 1. FIG. 6 is a schematic view illustrating a band structure of the light-emitting layer according to the comparative example illustrated in FIG. 4. In FIG. 5 and FIG. 6, the highest occupied molecular orbital (HOMO) and the lowest unoccupied molecular orbital (LUMO) of each of the hole transport layer HTL, the matrix material Mx, the quantum dots QD, and the electron transport layer ETL, and the band gap therebetween are indicated by rectangles. The upper side of the rectangle corresponds to the LUMO, and the lower side of the rectangle corresponds to the HOMO.

As indicated by the solid arrow in FIG. 5, in the configuration example according to the disclosure, electrons are injected from the electron transport layer ETL into the quantum dot QD over the energy barrier by the p-type semiconductor portion Mp. On the other hand, as indicated by the solid arrow in FIG. 6, in the configuration of the comparative example, electrons are injected from the electron transport layer ETL into the quantum dot QD over the energy barrier by the i-type semiconductor portion Mi. The energy barrier by the p-type semiconductor portion Mp is larger than the energy barrier by the i-type semiconductor portion Mi. Therefore, the efficiency of electron injection into the light-emitting layer EL according to the disclosure is lower than that in the comparative example.

In addition, electrons traversing the light-emitting layer EL in the configuration example according to the disclosure pass through both the p-type semiconductor portion Mp and the i-type semiconductor portion Mi. On the other hand, in the configuration of the comparative example, electrons traversing the light-emitting layer EL pass only through the i-type semiconductor portion Mi. The electron mobility of the p-type semiconductor portion Mp is smaller than the electron mobility of the i-type semiconductor portion Mi. Therefore, the electron mobility in the light-emitting layer EL according to the disclosure is lower than that in the comparative example.

The light-emitting layer EL of the comparative example has a problem of poor carrier balance. The light-emitting layer EL containing an inorganic semiconductor tends to have higher electron injection efficiency than a light-emitting layer containing an organic ligand, and electrons are likely to be excessively injected into the light-emitting layer EL. In addition, an inorganic semiconductor tends to have higher electron mobility than an organic ligand, and electrons cross the light-emitting layer EL and easily recombine with holes at the boundary between the hole transport layer HTL and the light-emitting layer EL and in the vicinity thereof. Therefore, the external quantum efficiency (EQE) of the light-emitting element 110 of the comparative example is low.

On the other hand, the light-emitting layer EL according to the disclosure has lower electron injection efficiency and electron mobility than those of the comparative example as described above. Therefore, the carrier balance of the light-emitting layer EL according to the disclosure is improved, and the EQE of the light-emitting element 10 is high.

To improve the carrier balance, the hole carrier concentration in the p-type semiconductor portion Mp is preferably about 10¹⁶ cm⁻³ or more. Further, the hole carrier concentration in the p-type semiconductor portion Mp is preferably about 10²¹ cm⁻³ or less so as not to exceed the range of the so-called “doping concentration”. The matrix material Mx may have a portion having the hole carrier concentration of about 10¹⁶ cm⁻³ or more and about 10²¹ cm⁻³ or less. This portion functions as the p-type semiconductor portion Mp and provides an effect of improving the EQE of the light-emitting element 10. When the matrix material Mx includes a group II-VI semiconductor and the p-type semiconductor portion Mp contains carbon (C) as an example, the carbon concentration in the p-type semiconductor portion Mp is preferably about 10¹⁶ cm⁻³ or more and 10²¹ cm⁻³ or less. When converted into a concentration per light-emitting layer EL including the quantum dots QD, the carbon concentration is preferably about 10¹² cm⁻³ or more and 10²¹ cm⁻³ or less. The same applies to the case where the matrix material Mx includes a group II-VI semiconductor and the p-type semiconductor portion Mp contains, for example, silicon (Si), germanium (Ge), and tin (Sn).

As described above, the current flowing through the light-emitting layer EL includes the current I₁ that flows through the quantum dot QD and contributes to light emission and the current I₂ that flows while avoiding the quantum dot QD and does not contribute to light emission. When the value of the hole carrier concentration in the p-type semiconductor portion Mp is 10¹⁹ cm⁻³ or more, the electric resistance of the p-type semiconductor portion Mp is large due to carrier compensation, and the current I₂ that does not contribute to light emission is small. Therefore, the current I₁ contributing to light emission is large. To improve the luminous efficiency of the light-emitting element 10, the value of the hole carrier concentration in the p-type semiconductor portion Mp is preferably 10¹⁹ cm⁻³ or more and 10²¹ cm⁻³ or less. When the matrix material Mx includes a group II-VI semiconductor and the p-type semiconductor portion Mp contains carbon (C), the value of the carbon concentration in the p-type semiconductor portion Mp is preferably about 10¹⁹ cm⁻³ or more and 10²¹ cm⁻³ or less.

### Manufacturing Method 1

Hereinafter, a method for manufacturing the light-emitting element 10 illustrated in FIG. 1 will be described in a case where the p-type semiconductor portion Mp contains zinc sulfide (ZnS) doped with carbon (C). The manufacturing method in a case where the p-type semiconductor portion Mp contains a material other than zinc sulfide doped with carbon will be understood from the following description, and thus the description thereof will be omitted.

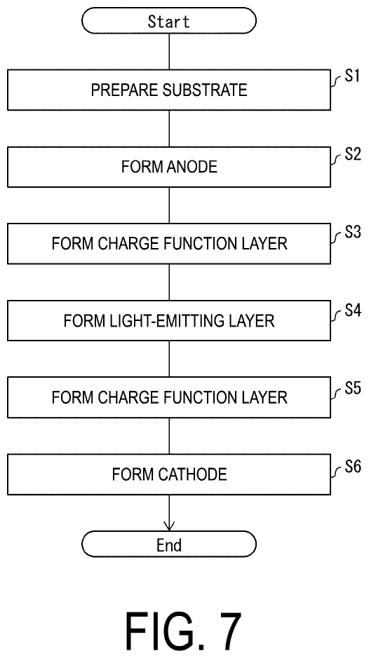

FIG. 7 is a flowchart illustrating an example of a method for manufacturing the light-emitting element illustrated in FIG. 1. As illustrated in FIG. 7, a substrate is prepared (step S1), the anode E1 is formed on the substrate (step S2), and the charge function layer F1 is formed on the anode E1 (step S3). Then, the light-emitting layer EL is formed on the charge function layer F1 (step S4), the charge function layer F2 is formed on the light-emitting layer EL (step S5), and the cathode E2 is formed on the charge function layer F2 (step S6).

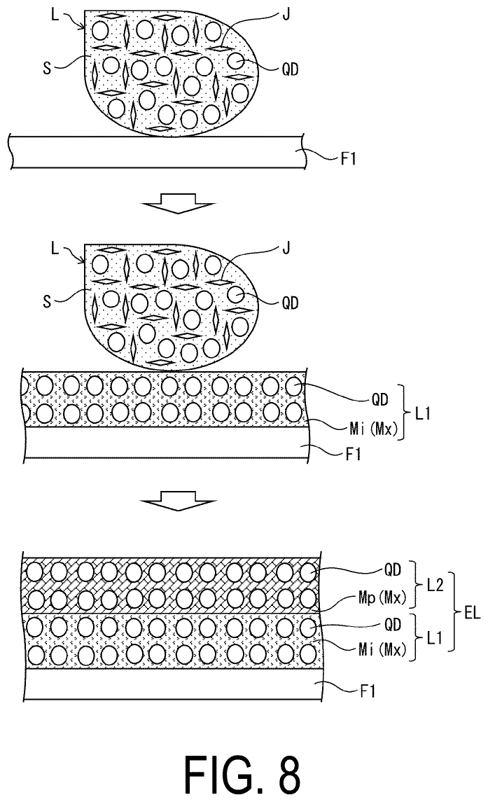

FIG. 8 includes cross-sectional process views illustrating an example of the forming process of the light-emitting layer according to the present embodiment. Referring to FIG. 7, when steps S1 to S6 are performed in this order, the light-emitting layer EL can be formed as illustrated in FIG. 8. In step S4, first, a quantum dot dispersion liquid L is applied onto the charge function layer F1. The quantum dot dispersion liquid L contains a precursor J of the matrix material Mx, the plurality of quantum dots QD, and a solvent S. Next, the solvent S is volatilized and/or decomposed from the applied quantum dot dispersion liquid L by firing. Subsequently or simultaneously, the precursor J is modified to the matrix material Mx by firing. A lower layer L1 including the quantum dots QD and the i-type semiconductor portion Mi is formed by this application and firing.

Examples of the solvent S include organic solvents such as dimethyl sulfoxide (DMSO), N, N-dimethylformamide (DMF), N-methylformamide (NMF), formamide, N, N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, and diethyl sulfide. When the matrix material Mx is zinc sulfide, the precursor J may contain, for example, at least one of a metal acetate, a metal nitrate, and a metal halide as a metal source, and at least one of thiourea, N-methylthiourea, 1,3-dimethylthiourea, N,N′-dimethylthiourea, tetramethylthiourea, and thioacetamide as a sulfur source. Alternatively, the precursor J may contain a metal complex in which thiourea, N-methylthiourea, 1,3-dimethylthiourea, N,N′-dimethylthiourea, tetramethylthiourea, or thioacetamide is coordinated to a metal atom.

The i-type semiconductor portion Mi in the lower layer L1 is formed by firing the quantum dot dispersion liquid L at a high temperature. By the high-temperature firing, the organic compound is sufficiently decomposed, and carbon (C) does not remain in the matrix material Mx. In addition, the content ratio in the precursor J is adjusted so that the composition ratio of the inorganic semiconductor constituting the matrix material Mx is not biased. Further, the matrix material Mx is not doped with carbon and other acceptors. Here, the high-temperature firing is preferably performed at a temperature of 125° C. or more and 500° C. or less for 1 minute or more and 24 hours or less.

Next, as illustrated in FIG. 8, the quantum dot dispersion liquid L is applied onto the lower layer L1 and fired to form an upper layer L2 including the quantum dots QD and the p-type semiconductor portion Mp. The p-type semiconductor portion Mp in the upper layer L2 is formed by firing the quantum dot dispersion liquid L at a low temperature. As a by-product of decomposition of the solvent S and modification of the precursor J, carbon (C) may remain in the light-emitting layer EL. By firing the quantum dot dispersion liquid L at a low temperature, the decomposition of the organic compound becomes insufficient. As a result, the organic compound remains in a partially decomposed state or an intact state, and carbon remains. Carbon (C) functions as an acceptor in zinc sulfide (ZnS), and the p-type semiconductor portion Mp is formed. Here, the low-temperature firing is preferably performed at a temperature of 60° C. or more and 125° C. or less for 1 minute or more and 24 hours or less.

The light-emitting layer EL is not limited to include the two layers of the lower layer L1 and the upper layer L2, and may be formed to include three or more layers.

### Manufacturing Method 2

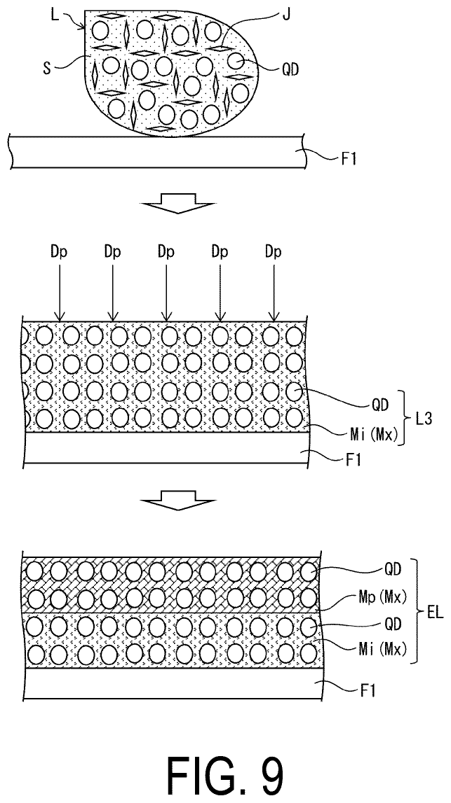

FIG. 9 includes cross-sectional process views illustrating another example of a forming process of the light-emitting layer according to the present embodiment. Referring again to FIG. 7, when steps S1 to S6 are performed in this order, the light-emitting layer EL can be formed as illustrated in FIG. 9. In step S4, first, the quantum dot dispersion liquid L is applied onto the charge function layer F1 and fired to form a layer L3 including the quantum dots QD and the i-type semiconductor portion Mi. Then, the i-type semiconductor portion Mi is converted into the p-type semiconductor portion Mp only in the upper portion of the layer L3. For example, only the upper portion of the matrix material Mx is doped with a carbon-containing material Dp.

### Manufacturing Method 3

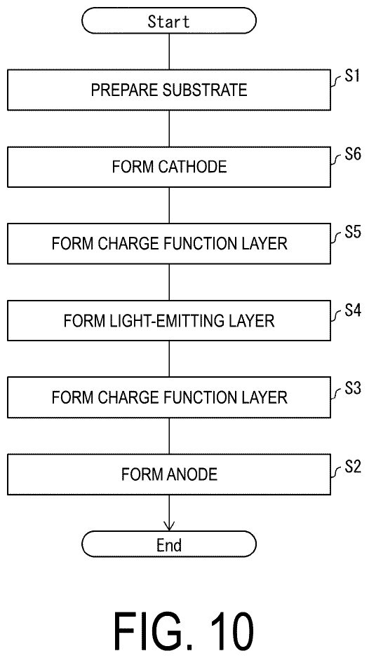

FIG. 10 is a flowchart illustrating another example of a method for manufacturing the light-emitting element illustrated in FIG. 1. As illustrated in FIG. 10, a substrate is prepared (step S1), the cathode E2 is formed on the substrate (step S6), and the charge function layer F2 is formed on the cathode E2 (step S5). Then, the light-emitting layer EL is formed on the charge function layer F2 (step S4), the charge function layer F1 is formed on the light-emitting layer EL (step S3), and the anode E1 is formed on the charge function layer F1 (step S2).

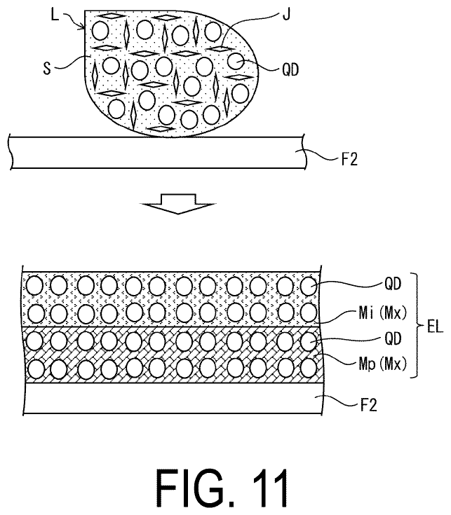

FIG. 11 includes cross-sectional process views illustrating another example of the forming process of the light-emitting layer according to the present embodiment. Referring to FIG. 10, when step S1 and step S6 to step S2 are performed in this order, the light-emitting layer EL can be formed as illustrated in FIG. 11. In step S4, the quantum dot dispersion liquid L is applied onto the charge function layer F1 and fired to form the light-emitting layer EL. Carbon (C) tends to remain so as to be distributed more on the lower side than on the upper side of the matrix material Mx. Therefore, the p-type semiconductor portion Mp is formed on the lower side of the matrix material Mx, and the i-type semiconductor portion Mi is formed on the upper side thereof. Here, the firing is preferably performed at a temperature of 60° C. or more and 125° C. or less for 1 minute or more and 24 hours or less.

### Quantum Dot Dispersion Liquid

In the present embodiment, the quantum dot dispersion liquid L described above is, for example, a solution containing the quantum dots QD with which halide ions 16H are coordinated. Thus, in the present embodiment, for example, a step of obtaining the quantum dots QD with which the halide ions 16H are coordinated is performed as a preceding step to a step of synthesizing the quantum dot dispersion liquid L containing the quantum dots QD. To be more specific, a substitution step of substituting ligands coordinated with the quantum dots QD is performed.

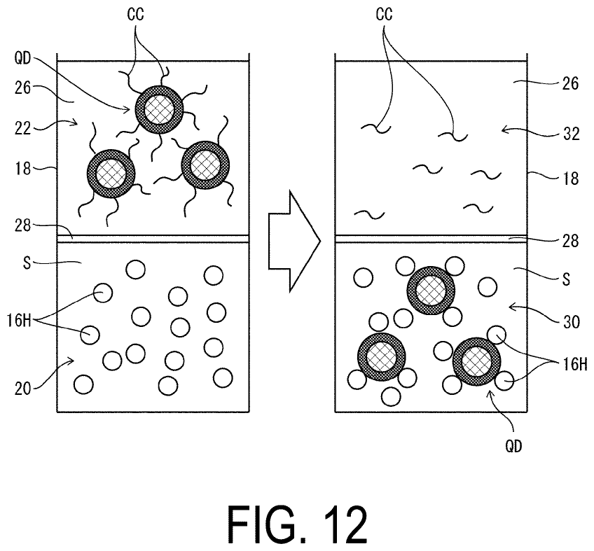

FIG. 12 includes cross-sectional process views for describing the substitution step described above. As illustrated in the view on the left side of FIG. 12, in the substitution step, first, a first solution 20 in which the halide ions 16H are dissolved and a second solution 22 in which the quantum dots QD with which carbon chains CC as organic ligands are coordinated are dispersed are injected into a container 18. The first solution 20 includes a first solvent S in which the halide ions 16H are soluble, and the second solution 22 includes a second solvent 26 in which the carbon chains CC are soluble. For example, the second solvent 26 has a polarity different from that of the first solvent S and has a specific gravity lower than that of the first solvent S. To more clearly distinguish the boundary between the first solution 20 and the second solution 22, a separation liquid 28 having a specific gravity and polarity between those of the first solvent S and the second solvent 26 may be injected into the container 18.

The first solvent S well disperses the precursor of the matrix material Mx and the quantum dots QD with which the halide ions 16H are coordinated. In addition, the first solvent S may be a polar solvent having a polarity higher than that of the second solvent 26. The second solvent 26 is desirably a non-polar solvent that is immiscible to the first solvent S.

The carbon chain CC may be a carbon chain to be generally used as a ligand of the quantum dot QD. The second solvent 26 is a solvent in which the carbon chains CC are soluble, and thus the quantum dots QD with which the carbon chains CC are coordinated are easily dispersed in the second solution 22. In addition, the halide ions 16H are dissolved in the first solution 20 in an excessive amount exceeding the amount of the halide ions 16H capable of being coordinated with the quantum dots QD. A concentration of the halide ions in the first solvent S is preferably 0.01 mol/l or more, and more preferably 0.1 mol/l or more.

Next, the container 18 containing the first solution 20 and the second solution 22 described above is vibrated at a high speed by a stirrer to stir the first solution 20 and the second solution 22. To improve stirring efficiency, a stirring bar may be put into the container 18. In other words, the step of stirring the first solution 20 and the second solution 22 is a step of treating the quantum dots QD with the halide ions 16H, in particular, a step of generating the quantum dots QD with which the halide ions 16H are coordinated.

Here, as described above, the first solution 20 contains an excessive amount of the halide ions 16H. In general, when two or more kinds of ligands are contained in a solution in which the quantum dots QD are dispersed, the ligands to be coordinated with the quantum dots QD are in an equilibrium state between the ligands in the solution. Thus, when the first solution 20 and the second solution 22 are stirred, at least a part of the ligands to be coordinated with the quantum dots QD is substituted from the carbon chains CC to the halide ions 16H.

For example, the solutions in the container 18 are stirred for at least one minute or longer. In addition, the solutions in the container 18 may be stirred at a frequency of 10 times per minute for 1 hour with the temperature of the solutions in the container 18 set to 25° C. Under such conditions, it can be said that the probability that the ligands coordinated with the quantum dots QD in the container 18 are replaced to the halide ions 16H is sufficiently high. In addition, to prevent water, oxygen, or the like in the air from being mixed with the solutions in the container 18, it is more desirable that the solutions in the container 18 be stirred in an atmosphere of nitrogen, argon, or the like.

Accordingly, by the stirring, as illustrated in the view on the right side of FIG. 12, a third solution 30 in which the quantum dots QD with which the halide ions 16H are coordinated are dispersed in the first solvent S and a fourth solution 32 in which the carbon chains CC are dissolved in the second solvent 26 are obtained in the container 18. As described above, the quantum dots QD with which the halide ions 16H are coordinated are obtained in the third solution 30. Note that the stirring may be completed when the liquid in the container 18 is irradiated with ultraviolet light or the like and it is confirmed that the liquid layer emitting light moves from the upper side to the lower side of the container 18.

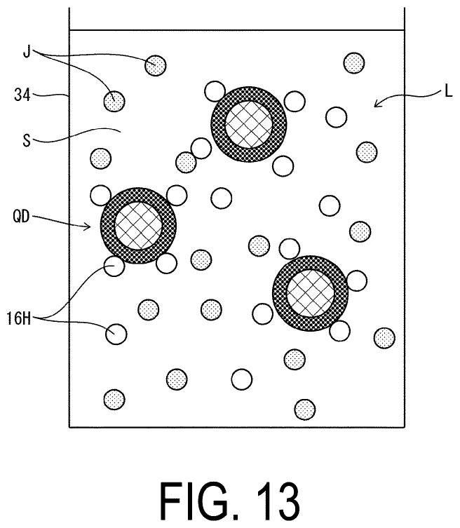

Next, a quantum dot dispersion liquid in which the quantum dots QD with which the halide ions 16H are coordinated are dispersed is synthesized. The quantum dot dispersion liquid according to the present embodiment will be described in detail with reference to FIG. 13. FIG. 13 is a schematic view illustrating a quantum dot dispersion liquid. For example, subsequent to the stirring, only the third solution 30 is extracted from the container 18 by a dropper or the like and injected into a container 34 illustrated in FIG. 13.

Here, a solution in which the precursor J of the matrix material Mx is dispersed in the first solvent S in advance may be injected into the container 18. Therefore, as illustrated in FIG. 13, the quantum dot dispersion liquid L in which the precursor J and the quantum dots QD with which the halide ions 16H are coordinated are dispersed in the first solvent S is synthesized.

### Evaluation of Impurity Concentration

The carbon concentration in the light-emitting layer EL can be measured by using any one of Secondary Ion Mass Spectrometry (SIMS), Auger Electron Spectroscopy (AES), Gas Chromatograph Mass Spectrometry (GCMS), Fourier Transform Infrared Spectroscopy (FTIR), X-ray Photoelectron Spectroscopy (XPS), and Energy Dispersive X-ray Spectroscopy (EDX), or by using any two or more of them in combination.

It is most preferred to use SIMS when all of the above equipment is available and the accuracy levels are the same. AES is preferably used next, followed by GCMS, FTIR, XPS, and EDX in that order. The priority order of the measurement results is the same as the preferred order.

The carbon concentration in the light-emitting layer EL including the quantum dots QD may be converted into the carbon concentration in the matrix material Mx not including the quantum dots QD. The particle diameter of the quantum dot QD, the shape of the quantum dot QD, and the number of quantum dots QD per cross-sectional area of the light-emitting layer EL can be measured using a transmission electron microscope (TEM). The distribution of the quantum dots QD in the light-emitting layer EL is random. By geometric calculation based on these, the volume ratio of the quantum dots QD to the light-emitting layer EL can be calculated and the volume ratio of the matrix material Mx to the light-emitting layer EL can be calculated.

Note that before converting the carbon concentration, it is preferable to confirm that the quantum dot QD does not contain carbon. In addition, when the p-type semiconductor portion Mp contains an impurity other than carbon, a doping material, or an acceptor, the impurity concentration can be similarly measured and converted, and it is preferable to confirm in advance that the quantum dot QD does not contain an impurity.

### Example 1

The light-emitting element 10 according to Example 1 was produced with the configuration illustrated in FIG. 1. The matrix material Mx contained ZnS, and the p-type semiconductor portion Mp contained C (carbon). The carbon concentration in the p-type semiconductor portion Mp was 10¹⁹ cm⁻³ or more and 10²¹ cm⁻³ or less at any position.

### Modified Example

As illustrated in FIG. 1, the p-type semiconductor portion Mp may be distributed with a uniform thickness, may be continuously distributed, or may be distributed so as to cover the upper surface of the light-emitting layer EL. On the other hand, the distribution of the p-type semiconductor portion Mp is not limited thereto, and may be any distribution. A modified example of the configuration of the light-emitting element according to the present embodiment will be described below.

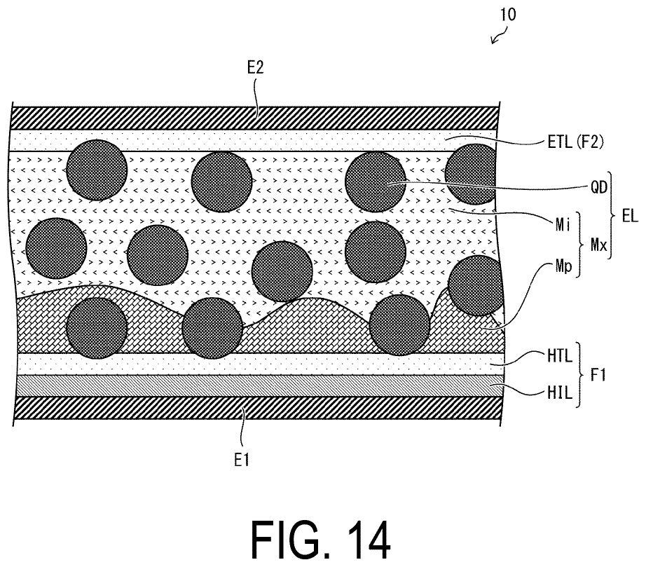

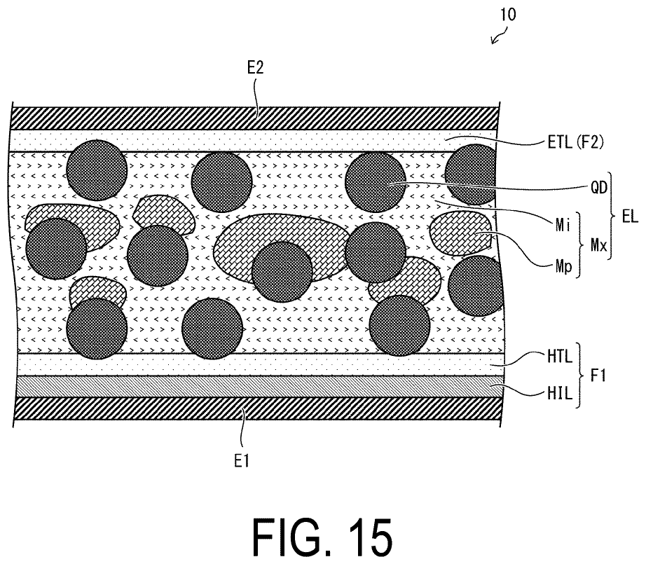

FIG. 14 and FIG. 15 each are a cross-sectional view illustrating the modified example of the configuration of the light-emitting element according to the present embodiment. As illustrated in FIG. 14, the p-type semiconductor portion Mp may be distributed with a non-uniform thickness or may be distributed so as to cover the lower surface of the light-emitting layer EL. As illustrated in FIG. 15, the p-type semiconductor portion Mp may be intermittently distributed or may be distributed inside the light-emitting layer EL.

By combining the examples of FIG. 1, FIG. 14, and FIG. 15, for example, the p-type semiconductor portion Mp may be continuously distributed with a non-uniform thickness so as to cover the upper surface of the light-emitting layer EL, or may be intermittently distributed so as to cover the upper surface of the light-emitting layer EL. Further, for example, the p-type semiconductor portion Mp may be continuously distributed with a uniform thickness so as to cover the lower surface of the light-emitting layer EL, or may be intermittently distributed so as to cover the lower surface of the light-emitting layer EL. In addition, for example, the p-type semiconductor portion Mp may be continuously distributed with a uniform thickness inside the light-emitting layer EL, or may be continuously distributed with a non-uniform thickness inside the light-emitting layer EL.

In the light-emitting layer EL, preferably, the p-type semiconductor portion Mp is located on the cathode E2 side in the matrix material Mx, and the i-type semiconductor portion Mi is located on the anode E1 side in the matrix material Mx. In other words, it is preferable that the hole carrier concentration in the portion of the matrix material Mx on the cathode E2 side be higher than the hole carrier concentration in the portion of the matrix material Mx on the anode E1 side. According to this configuration, the carrier balance in the light-emitting layer EL is further improved. In addition, accumulation of holes at the boundary between the light-emitting layer EL and the electron transport layer ETL can be reduced. When the matrix material Mx includes a group II-VI semiconductor and the p-type semiconductor portion Mp includes, for example, carbon (C), it is preferable that the carbon concentration in the portion of the matrix material Mx on the cathode E2 side be higher than the carbon concentration in the portion of the matrix material Mx on the anode E1 side. The hole carrier concentration or the carbon concentration in the matrix material Mx may change stepwise or continuously. The same applies to the case where the matrix material Mx includes a group II-VI semiconductor and the p-type semiconductor portion Mp contains, for example, silicon (Si), germanium (Ge), and tin (Sn).

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

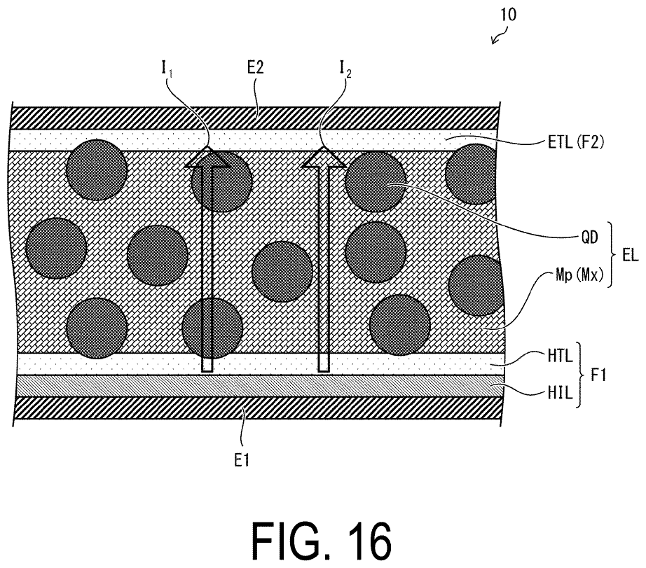

FIG. 16 is a cross-sectional view illustrating a configuration example of a light-emitting element according to an embodiment of the disclosure. As illustrated in FIG. 16, the configuration according to a second embodiment is similar to the configuration according to the first embodiment described above except that the entire matrix material Mx is the p-type semiconductor portion Mp.

### Manufacturing Method

Hereinafter, a method for manufacturing the light-emitting element 10 illustrated in FIG. 16 will be described in a case where the p-type semiconductor portion Mp contains zinc sulfide (ZnS) doped with carbon (C). The manufacturing method in a case where the matrix material Mx contains a material other than zinc sulfide will be understood from the following description, and thus description thereof will be omitted.

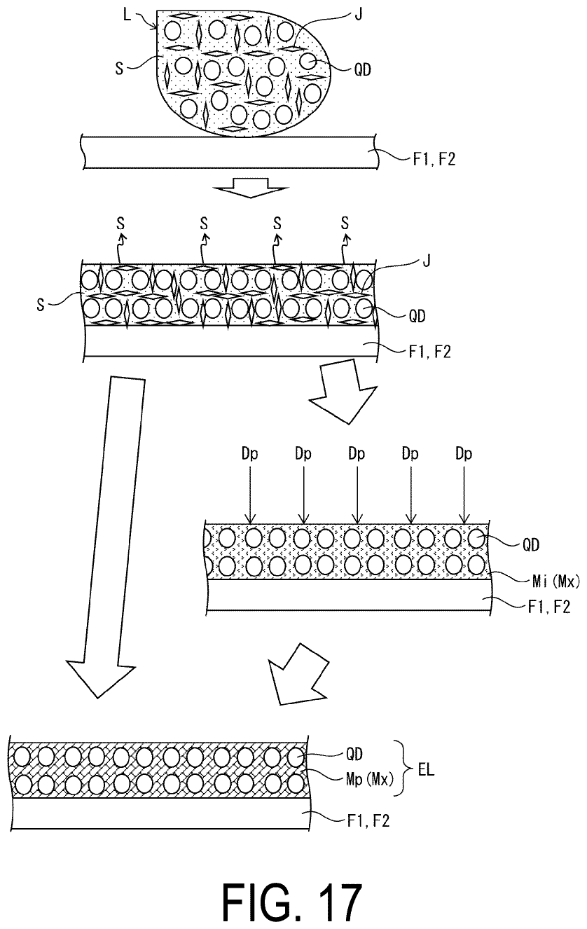

FIG. 17 includes cross-sectional process views illustrating an example of the forming process of the light-emitting layer according to the present embodiment. When step S1 to step S6 are performed in this order with reference to FIG. 7 again, or when step S1 and step S6 to step S1 are performed in this order with reference to FIG. 10 again, the light-emitting layer EL can be formed as illustrated in FIG. 17 in both cases. In step S4, first, the quantum dot dispersion liquid L is applied to the charge function layer F1 or the charge function layer F2 and fired to form the light-emitting layer EL including the quantum dots QD and the p-type semiconductor portion Mp.

The p-type semiconductor portion Mp may be formed by firing the quantum dot dispersion liquid L at a low temperature. Alternatively, the i-type semiconductor portion Mi may be formed by high-temperature firing and the i-type semiconductor portion Mi may be converted into the p-type semiconductor portion Mp.

### Third Embodiment

Another embodiment of the disclosure will be described below.

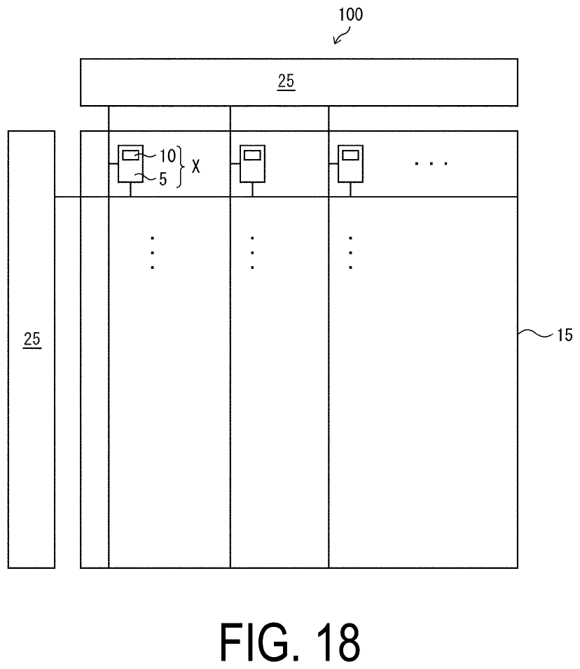

FIG. 18 is a plan view illustrating a configuration example of a display device according to an embodiment of the disclosure. As illustrated in FIG. 18, a display device 100 includes a display portion 15 including a plurality of subpixels X, and a driver circuit 25 for driving the display portion 15. For example, the subpixel X includes the light-emitting element 10 and the pixel circuit 5 described in the first or second embodiment.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting element comprising:
an anode and a cathode; and
a light-emitting layer located between the anode and the cathode,
wherein the light-emitting layer includes a plurality of quantum dots and a matrix material filling a space between the plurality of quantum dots, and
the matrix material comprises a p-type semiconductor portion and an i-type semiconductor portion having:
the i-type semiconductor portion including a group IV semiconductor, and the p-type semiconductor portion including a group IV semiconductor doped with a group III element,
the i-type semiconductor portion including a group III-V semiconductor, and the p-type semiconductor portion including a group III-V semiconductor doped with a group II element,
the p-type semiconductor portion and the i-type semiconductor portion including a group III-V semiconductor, and the group III-V semiconductor included in the p-type semiconductor portion having a group V element more than a group III element,
the i-type semiconductor portion including a group II-VI semiconductor, and the p-type semiconductor portion including a group II-VI semiconductor doped with a group IV element, or
the p-type semiconductor portion and the i-type semiconductor portion including a group II-VI semiconductor, and the group II-VI semiconductor included in the p-type semiconductor portion having a group VI element more than a group II element.

2. The light-emitting element according to claim 1,
wherein the matrix material fills a region in the space surrounded by two straight lines in contact with outer peripheries of a first quantum dot and a second quantum dot, among the plurality of quantum dots, and facing outer peripheries of the first quantum dot and the second quantum dot in a cross-sectional view of the light-emitting layer.

3.-12. (canceled)

13. A light-emitting element comprising:
an anode and a cathode; and
a light-emitting layer located between the anode and the cathode,
wherein the light-emitting layer includes a plurality of quantum dots and a matrix material filling a space between the plurality of quantum dots,
the matrix material includes a p-type semiconductor portion, and
a hole carrier concentration in the p-type semiconductor portion is 10¹⁶ cm⁻³ or more and 10²¹ cm⁻³ or less.

14. The light-emitting element according to claim 1,
wherein a value of a hole carrier concentration in the p-type semiconductor portion is 10¹⁹ cm⁻³ or more and 10²¹ cm⁻³ or less.

15. The light-emitting element according to claim 1,
wherein the p-type semiconductor portion is located on a cathode side in the matrix material.

16. A light-emitting element comprising:
an anode and a cathode; and
a light-emitting layer located between the anode and the cathode,
wherein the light-emitting layer includes a plurality of quantum dots and a matrix material filling a space between the plurality of quantum dots,
the matrix material includes a p-type semiconductor portion, and
a hole carrier concentration in a portion in the matrix material on a cathode side is higher than a hole carrier concentration in a portion in the matrix material on an anode side.

17. The light-emitting element according to claim 19,
wherein the p-type semiconductor portion includes the group IV element, and
the group IV element is carbon (C).

18. The light-emitting element according to claim 17,
wherein a carbon concentration in the p-type semiconductor portion is 10¹⁶ cm⁻³ or more and 10²¹ cm⁻³ or less.

19. The light-emitting element according to claim 17,
wherein a value of a carbon concentration in the p-type semiconductor portion is 10¹⁹ cm⁻³ or more and 10²¹ cm⁻³ or less.

20. The light-emitting element according to claim 17,
wherein a carbon concentration in a portion in the matrix material on a cathode side is higher than a carbon concentration in a portion in the matrix material on an anode side.

21. A display device comprising:
the light-emitting element according to claim 1.
